(19) United States
(12) Patent Application Publication
(10) Pub. No.: US 2023/0087103 A1
(43) Pub. Date: Mar. 23, 2023

(54) FIND MODEL SENSITIVITY USING PAYLOAD DATA

(71) Applicant: International Business Machines Corporation, Armonk, NY (US)

(72) Inventors: Ravi Chandra Chamarthy, Hyderabad (IN); Manish Anand Bhide, Hyderabad (IN); Trent A. Gray-Donald, Ottawa (CN)

(21) Appl. No.: 17/483,160

(22) Filed: Sep. 23, 2021

(51) Int. Cl. G06F 16/28; G06F 16/242; G06K 9/62; G06F 16/22

(52) U.S. Cl. CPC G06F 16/287; G06F 16/244; G06K 9/6215; G06F 16/2282

(57) ABSTRACT

An artificial intelligence model that performs operating the artificial intelligence model, which data taken collectively is uncollected payload data, storing the uncollected payload data to obtain a collected payload data set in the form of a plurality of data points, clustering the plurality of data points of payload data, calculating an average feature distance, calculating average label distance, grouping all given pairs of data points, and determining a plurality of close pairs of data points.

### BACKGROUND

The present invention relates generally to the fields of model sensitivity and payload data.

The Wikipedia entry for “Sensitivity Analysis” (as of Aug. 1, 2021) states, in part, as follows: “Sensitivity analysis is the study of how the uncertainty in the output of a mathematical model or system (numerical or otherwise) can be divided and allocated to different sources of uncertainty in its inputs. A related practice is uncertainty analysis, which has a greater focus on uncertainty quantification and propagation of uncertainty; ideally, uncertainty and sensitivity analysis should be run in tandem. The process of recalculating outcomes under alternative assumptions to determine the impact of a variable under sensitivity analysis can be useful for a range of purposes . . . ” (footnotes omitted).

When an AI model is scored, it is sent some feature values as input and the model generates some output such as model prediction, the confidence of the model in the prediction, etc. The input and the output of the model can be stored in a database table. This data is called as the “model payload data,” or, more simply, as the “payload.”

### SUMMARY

According to an aspect of the present invention, there is a method, computer program product and/or system for use with an artificial intelligence model, that performs the following operations (not necessarily in the following order): (i) operating the artificial intelligence model using input data and associated output data, which data taken collectively is uncollected payload data; (ii) storing the uncollected payload data to obtain a collected payload data set in the form of a plurality of data points; (iii) clustering the plurality of data points of payload data set to obtain a plurality of clusters, with each cluster including some data points of the plurality of data points; (iv) for each given cluster of the plurality of clusters, calculating an average feature distance for the given cluster; (v) for each given cluster of the plurality of clusters, calculating average label distance for the given cluster; (vi) for each given cluster of the plurality of clusters, grouping all given pairs of data points of the given cluster into a plurality of groups, with the grouping being based on label distance of the given pair of data points; and (vii) determining a plurality of close pairs of data points, where a close pair of data points is a pair of data points for which a feature distance between the pair of data points is less than the average feature distance for the cluster in which the pair of data points is included.

### BRIEF DESCRIPTION OF THE DRAWINGS

FIG. 1 is a block diagram view of a first embodiment of a system according to the present invention;

FIG. 2 is a flowchart showing a first embodiment method performed, at least in part, by the first embodiment system; and

FIG. 3 is a block diagram showing a machine logic (for example, software) portion of the first embodiment system.

### DETAILED DESCRIPTION

This Detailed Description section is divided into the following subsections: (i) The Hardware and Software Environment; (ii) Example Embodiment; (iii) Further Comments and/or Embodiments; and (iv) Definitions.

### I. The Hardware and Software Environment

The present invention may be a system, a method, and/or a computer program product at any possible technical detail level of integration. The computer program product may include a computer readable storage medium (or media) having computer readable program instructions thereon for causing a processor to carry out aspects of the present invention. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (for example, light pulses passing through a fiber-optic cable), or electrical signals transmitted through a wire.

A “storage device” is hereby defined to be anything made or adapted to store computer code in a manner so that the computer code can be accessed by a computer processor. A storage device typically includes a storage medium, which is the material in, or on, which the data of the computer code is stored. A single “storage device” may have: (i) multiple discrete portions that are spaced apart, or distributed (for example, a set of six solid state storage devices respectively located in six laptop computers that collectively store a single computer program); and/or (ii) may use multiple storage media (for example, a set of computer code that is partially stored in as magnetic domains in a computer's non-volatile storage and partially stored in a set of semiconductor switches in the computer's volatile memory). The term “storage medium” should be construed to cover situations where multiple different types of storage media are used.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

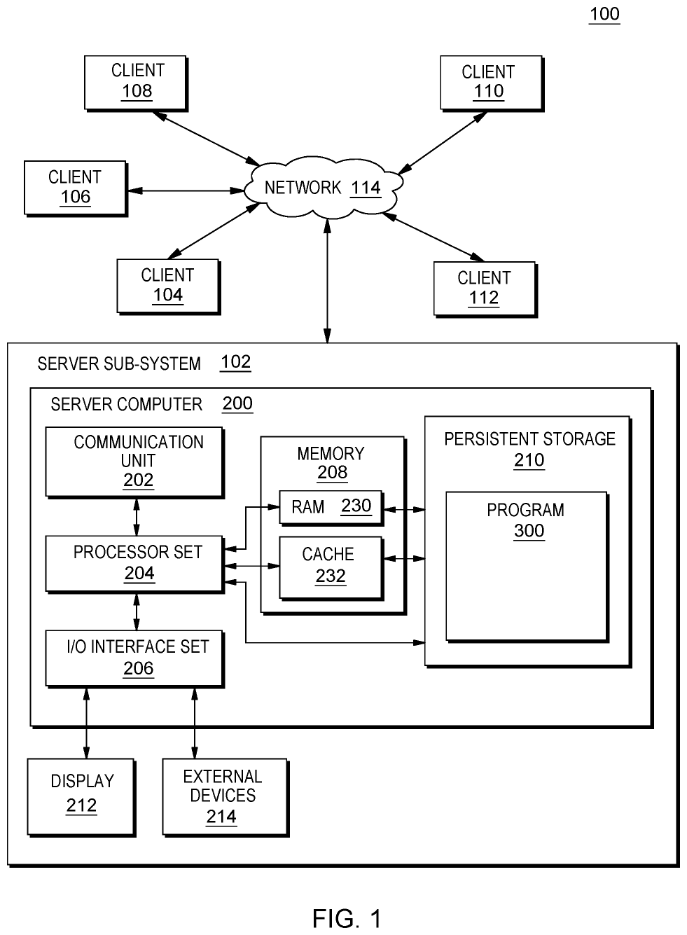

As shown in FIG. 1, networked computers system 100 is an embodiment of a hardware and software environment for use with various embodiments of the present invention. Networked computers system 100 includes: server subsystem 102 (sometimes herein referred to, more simply, as subsystem 102); client subsystems 104, 106, 108, 110, 112; and communication network 114. Server subsystem 102 includes: server computer 200; communication unit 202; processor set 204; input/output (I/O) interface set 206; memory 208; persistent storage 210; display 212; external device(s) 214; random access memory (RAM) 230; cache 232; and program 300.

Subsystem 102 may be a laptop computer, tablet computer, netbook computer, personal computer (PC), a desktop computer, a personal digital assistant (PDA), a smart phone, or any other type of computer (see definition of “computer” in Definitions section, below). Program 300 is a collection of machine readable instructions and/or data that is used to create, manage and control certain software functions that will be discussed in detail, below, in the Example Embodiment subsection of this Detailed Description section.

Subsystem 102 is capable of communicating with other computer subsystems via communication network 114. Network 114 can be, for example, a local area network (LAN), a wide area network (WAN) such as the Internet, or a combination of the two, and can include wired, wireless, or fiber optic connections. In general, network 114 can be any combination of connections and protocols that will support communications between server and client subsystems.

Subsystem 102 is shown as a block diagram with many double arrows. These double arrows (no separate reference numerals) represent a communications fabric, which provides communications between various components of subsystem 102. This communications fabric can be implemented with any architecture designed for passing data and/or control information between processors (such as microprocessors, communications and network processors, etc.), system memory, peripheral devices, and any other hardware components within a computer system. For example, the communications fabric can be implemented, at least in part, with one or more buses.

Memory 208 and persistent storage 210 are computer-readable storage media. In general, memory 208 can include any suitable volatile or non-volatile computer-readable storage media. It is further noted that, now and/or in the near future: (i) external device(s) 214 may be able to supply, some or all, memory for subsystem 102; and/or (ii) devices external to subsystem 102 may be able to provide memory for subsystem 102. Both memory 208 and persistent storage 210: (i) store data in a manner that is less transient than a signal in transit; and (ii) store data on a tangible medium (such as magnetic or optical domains). In this embodiment, memory 208 is volatile storage, while persistent storage 210 provides nonvolatile storage. The media used by persistent storage 210 may also be removable. For example, a removable hard drive may be used for persistent storage 210. Other examples include optical and magnetic disks, thumb drives, and smart cards that are inserted into a drive for transfer onto another computer-readable storage medium that is also part of persistent storage 210.

Communications unit 202 provides for communications with other data processing systems or devices external to subsystem 102. In these examples, communications unit 202 includes one or more network interface cards. Communications unit 202 may provide communications through the use of either or both physical and wireless communications links. Any software modules discussed herein may be downloaded to a persistent storage device (such as persistent storage 210) through a communications unit (such as communications unit 202).

I/O interface set 206 allows for input and output of data with other devices that may be connected locally in data communication with server computer 200. For example, I/O interface set 206 provides a connection to external device set 214. External device set 214 will typically include devices such as a keyboard, keypad, a touch screen, and/or some other suitable input device. External device set 214 can also include portable computer-readable storage media such as, for example, thumb drives, portable optical or magnetic disks, and memory cards. Software and data used to practice embodiments of the present invention, for example, program 300, can be stored on such portable computer-readable storage media. I/O interface set 206 also connects in data communication with display 212. Display 212 is a display device that provides a mechanism to display data to a user and may be, for example, a computer monitor or a smart phone display screen.

In this embodiment, program 300 is stored in persistent storage 210 for access and/or execution by one or more computer processors of processor set 204, usually through one or more memories of memory 208. It will be understood by those of skill in the art that program 300 may be stored in a more highly distributed manner during its run time and/or when it is not running. Program 300 may include both machine readable and performable instructions and/or substantive data (that is, the type of data stored in a database). In this particular embodiment, persistent storage 210 includes a magnetic hard disk drive. To name some possible variations, persistent storage 210 may include a solid state hard drive, a semiconductor storage device, read-only memory (ROM), erasable programmable read-only memory (EPROM), flash memory, or any other computer-readable storage media that is capable of storing program instructions or digital information.

The programs described herein are identified based upon the application for which they are implemented in a specific embodiment of the invention. However, it should be appreciated that any particular program nomenclature herein is used merely for convenience, and thus the invention should not be limited to use solely in any specific application identified and/or implied by such nomenclature.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

### II. Example Embodiment

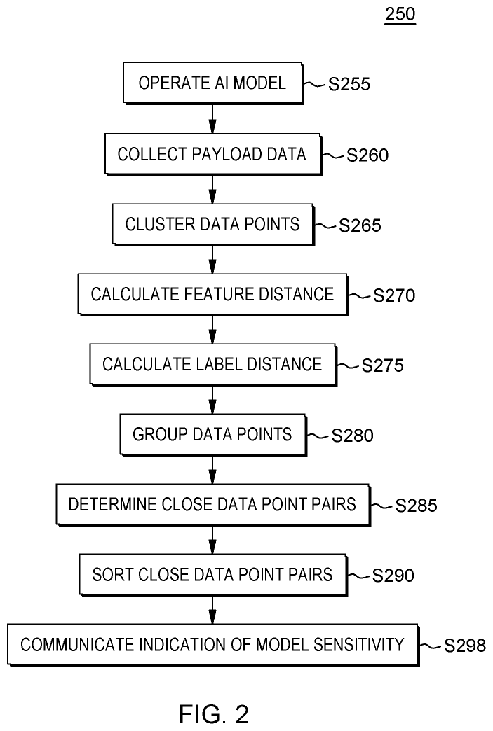

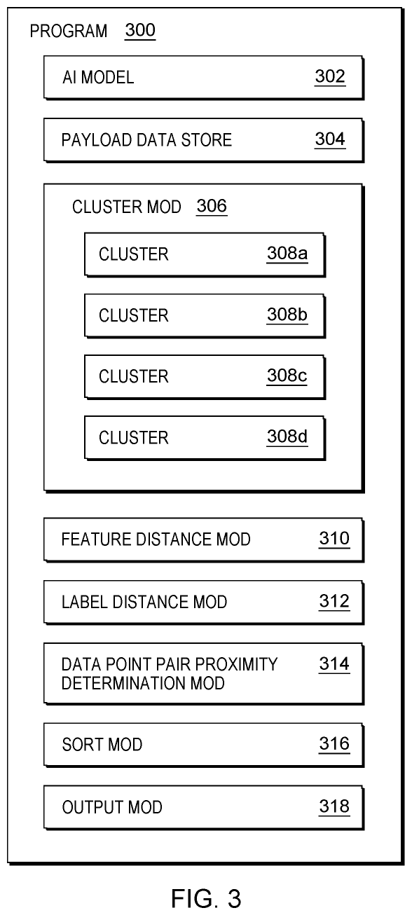

As shown in FIG. 1, networked computers system 100 is an environment in which an example method according to the present invention can be performed. As shown in FIG. 2, flowchart 250 shows an example method according to the present invention. As shown in FIG. 3, program 300 performs or controls performance of at least some of the method operations of flowchart 250. This method and associated software will now be discussed, over the course of the following paragraphs, with extensive reference to the blocks of FIGS. 1, 2 and 3.

Processing begins at operation S255, where artificial intelligence model 302 (also referred to as model 302) is operated to generate uncollected payload data. Uncollected payload data is the input and output data used in operation of model 302. The uncollected payload data is in the form of a plurality of data points.

Processing proceeds to operation S260, where collection module (“mod”) 302 collects the uncollected payload data and stores it in payload data store 304. The collected payload data is primarily made up of the plurality of data points (not separately shown in the Figures) mentioned in connection with the previous operation S255.

Processing proceeds to operation S265, where cluster mod 306 clusters a plurality of data points scored by model 302 over a predetermined time period to obtain clusters 308a, 308b, 308c and 308d. The scoring is performed by model 302 based on cosine distance between the feature values. In some embodiments, operation S265 is performed intermittently. In some embodiments, this operation is performed periodically (that is, at regular intervals, say, every three (3) hours).

Processing proceeds to operation S270, where feature distance mod 310 calculates the average feature distance between all pairs of points in each cluster of the plurality of clusters 308a, b, c, d.

Processing proceeds to operation S275, where, for each given cluster 308a, b, c, d, label distance mod 312 calculates the label distance between all pairs of data points in the given cluster. Way(s) to compute the label distance are discussed below.

Processing proceeds to operation S280, where cluster mod 306 groups pairs of data points of each cluster 308a, 308b, 308c and 308d on a cluster by cluster basis. The grouping of the groups of pairs of data points within each cluster is based on label distance. In this simple example: (i) the first group in each cluster will include data point pairs whose label distance is less than X (for example, if label distance is less than X=100, then that means that each data point in the data point pair that is grouped in the first group will have the same class label as each other); (ii) the second group in each cluster will include pairs of points whose label distance is greater than or equal to X (for example, the value of X can be set so that all of the data point pairs included in the second group will have different class labels from each other). Note that each of the clusters 308a, b, c, d will have Group 1 and Group 2 (groups not separately shown in the Figures).

Processing proceeds to operation S285, where data point pair proximity determination mod 314 finds all pairs of points in each group of each cluster where the points of the constituent pair meet certain proximity conditions. More specifically, under the proximity conditions, a given data point pair is a “close pair” if the points of the given data point pair have a feature distance that is less than the average feature distance for the cluster in which the given data point pair is included.

Processing proceeds to operation S290, where sort mod 316 sorts the close pairs based on decreasing value of label distance to obtain a list of sensitivity-indicative data point pairs where the data points of each sensitivity-indicative data point pair meet the following conditions: (i) the data points of the sensitivity-indicative data point pair have a relatively large label distance, and (ii) the data points of the sensitivity-indicative data point pair have a relatively small feature distance.

Processing proceeds to operation S298, where output mod 318 communicates the identity of the sensitivity-indicative data point pairs to a human user. In this example, the human user is the user of client subsystem 104 and the identity of the sensitivity-indicative data points are communicated from output mod 318 and through communication network 114. In this simple example, the top-80 data points where the model is showing sensitivity and we have 4 clusters (each with 2 groups), then we will pick up 10 data points from each group to form the 80 data points where the model exhibits sensitivity and returns it to the user.

### III. Further Comments and/or Embodiments

Some embodiments of the present invention recognize the following facts, potential problems and/or potential areas for improvement with respect to the current state of the art: (i) one of the important things that financial institutions like to test for their AI (artificial intelligence) models is the sensitivity of those models; (ii) a model is said to be sensitive if with a small change in the feature values, the model prediction changes; and/or (iii) as one can imagine, finding the areas of the domain where the model exhibits sensitivity can be an exhaustive and a very expensive task.

Some embodiments of the present invention recognize the following facts, potential problems and/or potential areas for improvement with respect to the current state of the art: (i) considers a scenario where a model has been deployed in production: (ii) when a new version of the model is built, it is first validated by a model risk management team; (iii) only after the approval of the model risk management team, is the model deployed to production; (iv) the model risk management team evaluates the model on different criteria such as fairness, quality, drift, etc.; (v) one important thing that financial institutions also care about is the sensitivity of the AI models; (vi) model sensitivity is identified using a trial and error method; (vii) data scientists sit with domain experts to think of different scenarios under which the model could potentially exhibit sensitivity; (viii) data is generated in those areas and checks if the model is showing any kind of sensitivity; and/or (ix) as one can imagine, such a technique is time consuming and very laborious.

Some embodiments of the present invention find model sensitivity using payload data (see, Definition, above, in the Background section). Some embodiments of the present invention are directed to a technique which involves clustering and using label distance and feature distance. Some embodiments of performing sensitivity detection can work without payload data. In other embodiments, the sensitivity detection techniques disclosed herein are applied along with payload data.

Some embodiments of the present invention may include one, or more, of the following operations, features, characteristics and/or advantages: (i) finds the sensitivity of an AI model by making use of the payload data encountered by the model in production; (ii) makes use of the payload data which has been processed by the earlier version of the model to find model sensitive areas; (iii) clusters the payload data; (iv) data points which are close to each other but have different class labels point to an area of the domain where the model exhibits sensitivity; and/or (v) finds and ranks the data points where the model exhibits sensitivity.

Some embodiments of the present invention may include one, or more, of the following operations, features, characteristics and/or advantages: (i) the payload data is to be regularly collected and stored in a data repository; (ii) at regular intervals, the payload data accumulated for the past (say) 7 days will be looked at; (iii) the data will be clustered; (iv) the distance measure to be used is the cosine similarity measure which will make use of the feature values of the data point (this is called the feature distance); (v) data points in a cluster will have similar feature values or feature values which are close to each other; (vi) defines a new metric to measure the distance between the class labels of two data points (this is called the label distance); and/or (vii) if two data points have the same class label, then the difference in the model confidence is determined and used as the label distance.

Some embodiments of the present invention may include one, or more, of the following operations, features, characteristics and/or advantages: (i) if two data points have different class labels, then in order to find the distance, the frequency of occurrence of the different class labels in a cluster is determined; (ii) using item (i) above, let the class labels and their frequency of occurrence in the cluster be: <C1,F1>, <C2, F2>, <C3,F3>, <C4, F4>, where C1 is the class label that occurs most frequency (F1 number of times) and C4 is the class label that occurs least frequently (F4 number of times); (iii) whenever the class label changes, the distance between the points needs to be more than the distance between two points with the same class label, so the minimum distance when class labels changes is 100; (iv) if the class label changes from say C1 to C2, then the distance will be lesser than if the class label changes from C1 to C4 where the intuition behind this is that C2 is more common class label as compared to C4; (v) in order to find the distance, the sum total of the distance between consecutive class labels needs to be determined (for example, it will be: (F2−F1)+(F3−F2)+(F4−F3). Let this value to F_diff_sum); and/or (vi) if the distance between two data points with labels C2 and C4 needs to be determined, then it will be computed as follows: 100+[(F2−F4)*100/F_diff_sum], where the distance between two points which moved from C1 to C4 will be: 144, whereas the distance between two points where the class label changed from C1 and C2 will be 115.

Some embodiments of the present invention may include one, or more, of the following operations, features, characteristics and/or advantages once the distance between all the data points has been determined, the following is performed: (i) for each cluster, two groups of data points is formed; (ii) the pair of data points whose label distance is less than 100 are in one group and the rest in the other group; (iii) for each group, the system will order the data points based on their feature distance; (iv) the system will then find all the pairs whose feature distance is less than the average feature distance of the points in the cluster where these data points will be considered close to each other; (v) for these data points, the system will sort them in decreasing order of their label distance where a list of data points whose labels are far from each other, but the features are close to each other, is determined; (vi) if the user is interested in finding the top-100 data points where the model is showing sensitivity and there are 10 clusters (each with 2 groups), then the system will pick up 5 data points from each group to form the 100 data points where the model exhibits sensitivity.

A method according to an embodiment of the present invention includes the following operations (not necessarily in the following order): (i) collects the payload data and finds the data points where the model exhibits sensitivity; (ii) clusters the data points using feature distance after the feature distance and the label distance is determined; (iii) the label distance is computed using the frequency of occurrence of the label in the cluster; (iv) determines the close data points using the feature distance; and (v) determines the sensitive data points based on the label distance.

Some embodiments of the present invention may include one, or more, of the following operations, features, characteristics and/or advantages: (i) finds model sensitivity using payload data; (ii) finds the machine learning model sensitivity using the runtime scored data or otherwise called payload data; (iii) measures the sensitivity of the machine learning model; (iv) finds the machine learning model sensitivity using only the runtime scored data or otherwise called payload data; (v) finds the ML (machine learning) model sensitivity using the runtime scored data or otherwise called payload data by identifying the data points in the payload data that exhibits sensitivity by measuring the feature distance and label distance and there by clustering the data points using feature distance; (vi) from the clusters, computes the label distance using the frequency of occurrence of the label; (vii) finds the close data points using the feature distance; (viii) finds the sensitive data points based on the label distance; (ix) measures the sensitivity of the machine learning model; and/or (x) discloses how AI does sensitivity analysis.

### IV. Definitions

Present invention: should not be taken as an absolute indication that the subject matter described by the term “present invention” is covered by either the claims as they are filed, or by the claims that may eventually issue after patent prosecution; while the term “present invention” is used to help the reader to get a general feel for which disclosures herein are believed to potentially be new, this understanding, as indicated by use of the term “present invention,” is tentative and provisional and subject to change over the course of patent prosecution as relevant information is developed and as the claims are potentially amended.

Embodiment: see definition of “present invention” above—similar cautions apply to the term “embodiment.”

And/or: inclusive or; for example, A, B “and/or” C means that at least one of A or B or C is true and applicable.

Including/include/includes: unless otherwise explicitly noted, means “including but not necessarily limited to.”

Module/Sub-Module: any set of hardware, firmware and/or software that operatively works to do some kind of function, without regard to whether the module is: (i) in a single local proximity; (ii) distributed over a wide area; (iii) in a single proximity within a larger piece of software code; (iv) located within a single piece of software code; (v) located in a single storage device, memory or medium; (vi) mechanically connected; (vii) electrically connected; and/or (viii) connected in data communication.

Computer: any device with significant data processing and/or machine readable instruction reading capabilities including, but not limited to: desktop computers, mainframe computers, laptop computers, field-programmable gate array (FPGA) based devices, smart phones, personal digital assistants (PDAs), body-mounted or inserted computers, embedded device style computers, application-specific integrated circuit (ASIC) based devices.

What is claimed is:

1. A computer-implemented method (CIM) for use with an artificial intelligence model, the CIM comprising:
operating the artificial intelligence model using input data and associated output data, which data taken collectively is uncollected payload data;
storing the uncollected payload data to obtain a collected payload data set in the form of a plurality of data points;
clustering the plurality of data points of payload data set to obtain a plurality of clusters, with each cluster including some data points of the plurality of data points;
for each given cluster of the plurality of clusters, calculating an average feature distance for the given cluster;
for each given cluster of the plurality of clusters, calculating average label distance for the given cluster;
for each given cluster of the plurality of clusters, grouping all given pairs of data points of the given cluster into a plurality of groups, with the grouping being based on label distance of the given pair of data points; and
determining a plurality of close pairs of data points, where a close pair of data points is a pair of data points for which a feature distance between the pair of data points is less than the average feature distance for the cluster in which the pair of data points is included.

2. The CIM of claim 1 further comprising:
sorting the close pairs of data points of the plurality of close pairs based on decreasing value of label distance obtain a list of sensitivity-indicative data point pairs where the data points of each sensitivity-indicative data point pair meet the following conditions: (i) the data points of the sensitivity-indicative data point pair have a relatively large label distance, and (ii) the data points of the sensitivity-indicative data point pair have a relatively small feature distance.

3. The CIM of claim 2 further comprising:
communicating the list of sensitivity-indicative data point pairs to a human user.

4. The CIM of claim 1 wherein the calculations of the average feature distances include determination of feature distances based on cosine distance techniques.

5. The CIM of claim 1 wherein the sensitivity-indicative data point pairs indicate uncertainty in the output of the artificial intelligence model that are allocated to different sources of uncertainty in its inputs.

6. The CIM of claim 1 wherein the storage of the uncollected payload data includes the following sub-operation:
storing the collected payload in a database table data structure.

7. A computer program product for use with an artificial intelligence model, the (CPP) comprising:
a set of storage device(s); and
computer code stored collectively in the set of storage device(s), with the computer code including data and instructions to cause a processor(s) set to perform at least the following operations:
operating the artificial intelligence model using input data and associated output data, which data taken collectively is uncollected payload data,
storing the uncollected payload data to obtain a collected payload data set in the form of a plurality of data points,
clustering the plurality of data points of payload data set to obtain a plurality of clusters, with each cluster including some data points of the plurality of data points, for each given cluster of the plurality of clusters, calculating an average feature distance for the given cluster,
for each given cluster of the plurality of clusters, calculating average label distance for the given cluster,
for each given cluster of the plurality of clusters, grouping all given pairs of data points of the given cluster into a plurality of groups, with the grouping being based on label distance of the given pair of data points, and
determining a plurality of close pairs of data points, where a close pair of data points is a pair of data points for which a feature distance between the pair of data points is less than the average feature distance for the cluster in which the pair of data points is included.

8. The CPP of claim 7 wherein the computer code further includes instructions for causing the processor(s) set to perform the following operation(s):
sorting the close pairs of data points of the plurality of close pairs based on decreasing value of label distance obtain a list of sensitivity-indicative data point pairs where the data points of each sensitivity-indicative data point pair meet the following conditions: (i) the data points of the sensitivity-indicative data point pair have a relatively large label distance, and (ii) the data points of the sensitivity-indicative data point pair have a relatively small feature distance.

9. The CPP of claim 8 wherein the computer code further includes instructions for causing the processor(s) set to perform the following operation(s):
communicating the list of sensitivity-indicative data point pairs to a human user.

10. The CPP of claim 7 wherein the calculations of the average feature distances include determination of feature distances based on cosine distance techniques.

11. The CPP of claim 7 wherein the sensitivity-indicative data point pairs indicate uncertainty in the output of the artificial intelligence model that are allocated to different sources of uncertainty in its inputs.

12. The CPP of claim 7 wherein the storage of the uncollected payload data includes the following sub-operation:
storing the collected payload in a database table data structure.

13. A computer system (CS) comprising for use with an artificial intelligence model, the CS comprising:
a processor(s) set;
a set of storage device(s); and
computer code stored collectively in the set of storage device(s), with the computer code including data and instructions to cause the processor(s) set to perform at least the following operations:
operating the artificial intelligence model using input data and associated output data, which data taken collectively is uncollected payload data,
storing the uncollected payload data to obtain a collected payload data set in the form of a plurality of data points,
clustering the plurality of data points of payload data set to obtain a plurality of clusters, with each cluster including some data points of the plurality of data points,
for each given cluster of the plurality of clusters, calculating an average feature distance for the given cluster,
for each given cluster of the plurality of clusters, calculating average label distance for the given cluster,
for each given cluster of the plurality of clusters, grouping all given pairs of data points of the given cluster into a plurality of groups, with the grouping being based on label distance of the given pair of data points, and
determining a plurality of close pairs of data points, where a close pair of data points is a pair of data points for which a feature distance between the pair of data points is less than the average feature distance for the cluster in which the pair of data points is included.

14. The CS of claim 13 wherein the computer code further includes instructions for causing the processor(s) set to perform the following operation(s):
sorting the close pairs of data points of the plurality of close pairs based on decreasing value of label distance obtain a list of sensitivity-indicative data point pairs where the data points of each sensitivity-indicative data point pair meet the following conditions: (i) the data points of the sensitivity-indicative data point pair have a relatively large label distance, and (ii) the data points of the sensitivity-indicative data point pair have a relatively small feature distance.

15. The CS of claim 14 wherein the computer code further includes instructions for causing the processor(s) set to perform the following operation(s):
communicating the list of sensitivity-indicative data point pairs to a human user.

16. The CS of claim 13 wherein the calculations of the average feature distances include determination of feature distances based on cosine distance techniques.

17. The CS of claim 13 wherein the sensitivity-indicative data point pairs indicate uncertainty in the output of the artificial intelligence model that are allocated to different sources of uncertainty in its inputs.

18. The CS of claim 13 wherein the storage of the uncollected payload data includes the following sub-operation:
storing the collected payload in a database table data structure.
